(19) United States
(12) Patent Application Publication
(10) Pub. No.: US 2024/0105837 A1
(43) Pub. Date: Mar. 28, 2024

(54) POWER SEMICONDUCTOR DEVICE, MEASUREMENT SYSTEM AND METHOD FOR DETERMINING A CURRENT OF A POWER SEMICONDUCTOR DEVICE

(71) Applicant: Infineon Technologies AG, Neubiberg (DE)

(72) Inventors: Ingo Dirnstorfer, Dreden (DE); Andreas Gneupel, Dresden (DE); Dmitry Balashov, Bannewitz Ot Wilmsdorf (DE); Markus Böhm, Dresden (DE); Christian Kemle, Mittelstetten (DE); Richard Springer, Dresden (DE)

(21) Appl. No.: 18/465,598

(22) Filed: Sep. 12, 2023

(30) Foreign Application Priority Data
Sep. 27, 2022 (DE) 102022124808.9

(51) Int. Cl. H01L 29/78; H01L 27/06; H01L 29/06; H01L 29/10; H01L 29/739; H01L 29/861

(52) U.S. Cl. CPC H01L 29/7815; H01L 27/0623; H01L 27/0629; H01L 29/0649; H01L 29/1095; H01L 29/7397; H01L 29/8611

(57) ABSTRACT

A power semiconductor device is proposed. The power semiconductor device includes a semiconductor body and a wiring area over a first surface of the semiconductor body. The power semiconductor device further includes a bipolar power semiconductor element including a first load electrode in the wiring area, an active area in the semiconductor body, and a second load electrode at a second surface of the semiconductor body. The power semiconductor device further includes a current sensing element including a pn or pin junction. The power semiconductor device further includes an optical window configured to allow electromagnetic radiation caused by an on-current of the bipolar power semiconductor element to pass to the current sensing element.

### TECHNICAL FIELD

The present disclosure relates to a power semiconductor device, in particular to a power semiconductor device including a bipolar semiconductor element and a sensing element.

### BACKGROUND

Technology development of new generations of power semiconductor devices, e.g. insulated gate bipolar transistors (IGBTs) or thyristors, aims at improving electric device characteristics and reducing costs by shrinking device geometries. Although costs may be reduced by shrinking device geometries, a variety of tradeoffs and challenges must be met when increasing device functionalities per unit area. For example, a trade-off between chip area consumption by sensing elements and reliability requirements of the power semiconductor device requires design optimization.

Thus, there is a need for an improved of power semiconductor device.

### SUMMARY

An example of the present disclosure relates to a power semiconductor device. The power semiconductor device includes a semiconductor body and a wiring area over a first surface of the semiconductor body. The power semiconductor device further includes a bipolar power semiconductor element comprising a first load electrode in the wiring area, an active area in the semiconductor body, and a second load electrode at a second surface of the semiconductor body. The power semiconductor device further includes a current sensing element including a pn or pin junction. The power semiconductor device further includes an optical window configured to allow electromagnetic radiation caused by an on-current of the bipolar power semiconductor element to pass to the current sensing element.

Another example of the present disclosure relates to a measurement system. The measurement system includes a power semiconductor device comprising a bipolar power semiconductor element and a current sensing element. The measurement system further includes a measurement device configured to determine a measure for an on-current of the bipolar power semiconductor element by forcing a voltage between a first pin and a second pin of the current sensing element and measuring a current through the first pin and the second pin.

Another example of the present disclosure relates to a method for determining a current of a power semiconductor device comprising a bipolar power semiconductor element and a current sensing element. The method includes determining a measure for an on-current of the bipolar power semiconductor element by forcing a voltage between the first pin and the second pin of the current sensing element and measuring a current through the first pin and the second pin.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of power semiconductor devices and measurement systems and together with the description serve to explain principles of the examples. Further examples are described in the following detailed description and the claims.

FIGS. 1A and 1B are partial cross-sectional views for illustrating an example of a power semiconductor device including a bipolar power semiconductor element and a temperature/current sensing element.

FIG. 2 is a partial cross-sectional view for illustrating an example of the temperature/current sensing element of a power semiconductor device.

FIG. 3 is an exemplary circuit diagram illustrating a serial connection on pn junction diodes of an example of a temperature/current sensing element of a power semiconductor device.

FIG. 4 is a schematic diagram for illustrating an exemplary measurement system.

FIG. 5 is an exemplary current vs. voltage graph of a temperature/current sensing element for illustrating measurement of current and temperature of the bipolar power semiconductor element.

### DETAILED DESCRIPTION

In the following detailed description, reference is made to the accompanying drawings, which form a part hereof and in which are shown by way of illustrations specific examples of power semiconductor devices and measurement systems. It is to be understood that other examples may be utilized, and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

Ranges given for physical dimensions include the boundary values. For example, a range for a parameter y from a to b reads as a y b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of a power semiconductor device may include a semiconductor body and a wiring area over a first surface of the semiconductor body. The power semiconductor device may further include a bipolar power semiconductor element comprising a first load electrode in the wiring area, an active area in the semiconductor body, and a second load electrode at a second surface of the semiconductor body. The power semiconductor device may further include a current sensing element including a pn or pin junction. The power semiconductor device may further include an optical window configured to allow electromagnetic radiation caused by an on-current of the bipolar power semiconductor element to pass to the current sensing element.

The power semiconductor device may be an integrated circuit, or a discrete semiconductor device or a semiconductor module, for example. The power semiconductor device may be or may include a bipolar power semiconductor element, e.g. a vertical bipolar power semiconductor element having a load current flow between the first surface and the second surface. The power semiconductor device may be used in automotive, industrial power control, power management, sensing solutions and security in Internet of Things applications The bipolar power semiconductor element may be or may include a power semiconductor diode, or a power semiconductor IGBT (insulated gate bipolar transistor), or a reverse conducting (RC) IGBT, or a power thyristor (e.g. a silicon controlled rectifier, SCR), or a power bipolar transistor. The power semiconductor device may be configured to conduct currents of more than 1 A or more than 10 A or even more than 30 A. For realizing a desired maximum load current, the bipolar power semiconductor element may be designed by a plurality of parallel-connected cells. The parallel-connected cells may, for example, be bipolar transistor cells, or thyristor cells, or IGBT cells, or diode cells formed in the shape of a strip or a strip segment. Of course, the device cells can also have any other shape, e.g., circular, elliptical, polygonal such as octahedral. The power semiconductor device may be further configured to block voltages between load electrodes, e.g. between emitter and collector of an IGBT or bipolar transistor, or between cathode and anode of a diode or thyristor, in the range of several hundreds or up to several thousands of volts, e.g. 30V, 40V, 60V, 80V, 100V, 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example. The power semiconductor device may also be or may also include a lateral semiconductor device, e.g. a lateral power semiconductor device, having a load current flow along a lateral direction, e.g. parallel to the first surface.

For example, the power semiconductor device may be implemented monolithically using a mixed technology. The power semiconductor device may be part of a discrete, BCD or Smart Power chip in one of the above application fields, for example.

The semiconductor body may include or consist of a semiconductor material from the group IV elemental semiconductors, IV-IV compound semiconductor material, III-V compound semiconductor material, or II-VI compound semiconductor material. Examples of semiconductor materials from the group IV elemental semiconductors include, inter alia, silicon (Si) and germanium (Ge). Examples of IV-IV compound semiconductor materials include, inter alia, silicon carbide (SiC) and silicon germanium (SiGe). Examples of III-V compound semiconductor material include, inter alia, gallium arsenide (GaAs), gallium nitride (GaN), gallium phosphide (GaP), indium phosphide (InP), indium gallium nitride (InGaN) and indium gallium arsenide (InGaAs). Examples of II-VI compound semiconductor materials include, inter alia, cadmium telluride (CdTe), mercury-cadmium-telluride (CdHgTe), and cadmium magnesium telluride (CdMgTe). For example, the semiconductor body may be a magnetic Czochralski, MCZ, or a float zone (FZ) or an epitaxially deposited silicon semiconductor body.

The first surface may be a front surface or a top surface of the semiconductor body, and the second surface may be a back surface or a rear surface of the semiconductor body, for example. The semiconductor body may be attached to a lead frame via the second surface, for example.

The wiring area over the first surface of the semiconductor body may include one or more than one, e.g. two, three, four or even more wiring levels. Each wiring level may be formed by a single one or a stack of conductive layers, e.g. metal layer(s) and/or highly doped semiconductor layer(s) (e.g. highly doped polycrystalline layers). For example, the wiring levels may include at least one of Cu, Au, AlCu, Ag, or alloys thereof. The wiring levels may be lithographically patterned, for example. Between stacked wiring levels, an interlayer dielectric structure may be formed. Openings may be formed in the interlayer dielectric structure for electrically interconnecting different wiring layers. For example, contact plug(s), or contact via(s) or contact line(s) may be formed in the openings in the interlayer dielectric structure to electrically connect parts, e.g. metal lines or contact areas, of different wiring levels to one another.

The first load electrode may be formed by at least one of the wiring levels, for example.

The wiring area may be arranged over the active area of the power semiconductor device. The active area may be an area where the device elements in the semiconductor body, e.g. a bipolar transistor cell array, or a thyristor cell array, or an IGBT cell array, or a diode cell array of a vertical power semiconductor device, are electrically connected to the wiring area via the first surface. Apart from the active area, the power semiconductor device may also include an edge termination area that at least partly surrounds the active area. The edge termination area may include a termination structure. In a blocking mode or in a reverse biased mode of the power semiconductor device, the blocking voltage between the active area and a field-free region laterally drops across the termination structure. The termination structure may have a higher or a slightly lower voltage blocking capability than the active area. The termination structure may include a junction termination extension (JTE) with or without a variation of lateral doping (VLD), one or more laterally separated guard rings, or any combination thereof, for example. An imide passivation may be arranged over the edge termination and/or wiring area, for example.

For example, the current sensing element may be an element that is used for sensing temperature and for sensing current of the power semiconductor element. This double-function may be implemented by sensing current or voltage of the pn or pin junction. For example, a photo current may be sensed, wherein the photo current is generated by absorption of electromagnetic radiation in the current sensing element and separating the generated charge carriers by the built-in electric field of the pn or pin junction or by the biased pn or pin junction. The sensed photo current may be used to determine the on-current of the bipolar power semiconductor element based on the electromagnetic radiation caused by the on-current of the bipolar power semiconductor element and passed to the current sensing element through the optical window. For example, current sensing element may further be configured to sense or to be used to sense a temperature of the bipolar power semiconductor element. In this case, the current sensing element may also be referred to as temperature/current sensing element.

The power semiconductor device allows for sensing both temperature and on-current of a bipolar power semiconductor element by the pn or pin junction of the current sensing element. This may allow for reducing chip area consumption caused by sensing elements by combining the temperature and current sensing function into a single element. Thereby, the trade-off between chip area consumption caused by sensing elements and reliability requirements of the power semiconductor devices may be improved.

For example, the optical window may comprise semiconductor material and dielectric material. The electromagnetic radiation caused by an on-current of the bipolar power semiconductor element, e.g. by a radiative recombination process of an electron-hole pair, may have an energy that is smaller than an energy bandgap of the semiconductor body, The optical window may thus include part of the semiconductor body that laterally extends from the power semiconductor element to the current sensing element. Apart from a direct path between the bipolar power semiconductor element, i.e. a position of generation of the electromagnetic radiation, and the current sensing element, i.e. a position of detection of the electromagnetic radiation, the electromagnetic radiation may also be reflected one or more times on the path between the bipolar power semiconductor element to the current sensing element. Reflection of the electromagnetic radiation may be caused by reflective elements, e.g. metal layer(s) in a wiring area over the first surface and/or the second surface.

The current sensing element may be arranged in the wiring area over the first surface. For example, the current sensing element may be formed in a semiconductor layer over the first surface. For example, the semiconductor layer may be a doped polycrystalline silicon semiconductor layer. The polycrystalline semiconductor layer may be the polycrystalline layer used as a gate electrode of a bipolar power semiconductor element formed as an IGBT, for example.

For example, the pn or pin junction of the current sensing element may be a monocrystalline or a polycrystalline or a nanocrystalline silicon pn or pin junction.

For example, a surface of the current sensing element may be textured. For example, the textured surface may be a (100) oriented first surface of a silicon semiconductor body, e.g. wafer. The current sensing element may be formed over the textured first surface in the wiring area or may be formed in the semiconductor body below the textured first surface, for example. In addition, also the second surface may be textured, the second surface may also be a (100) oriented surface of a silicon semiconductor body. The texture may be formed by anisotropic etching of silicon, e.g. by strongly aqueous alkaline media such as KOH-, NaOH- or TMAH-solutions. For (110) oriented Si wafers, alkaline etching results in formation of square-based pyramids with {111} surfaces.

For example, the power semiconductor device may further comprise a reflection layer configured to reflect the electromagnetic radiation back into the optical window. For example, the reflection layer may be part of the wiring area over the first surface of the semiconductor body. For example, the reflection layer may be formed by a metal of the wiring area that is located closest to the first surface, for example.

For example, the power semiconductor device may further include deep level impurities in the current sensing element. This may allow for multi-level absorption, and may thus allow for an improvement of the detection sensitivity of the electromagnetic radiation caused by the on-current of the bipolar power semiconductor element.

For example, the semiconductor body may be a silicon semiconductor body and the deep level impurities may include at least one of selenium, sulfur, thallium, zinc.

For example, the current sensing element may include a plurality of the pn or pin junctions connected in series or in parallel. The plurality of the pn or pin junctions may be subsequently arranged along a vertical direction and/or along a lateral direction.

For example, the power semiconductor device may further include a surface recombination reduction structure on a surface of the current sensing element. For example, the surface recombination reduction structure may allow for a reduced number of recombination centers at an interface to a semiconductor material of the current sensing element. For example, the surface recombination reduction structure may include one or more thin dielectric layers, e.g. SiO₂, SiN, or Al₂O₃. For example, a thickness of the surface recombination reduction structure may range from 1 nm to 100 nm.

For example, an equipotential plane in the pn or pin junction is predominantly parallel to a vertical direction. This may allow for reducing chip area consumption by the current sensing element and may thus contribute to improve the trade-off between chip area consumption by sensing elements and reliability requirements of the power semiconductor device.

For example, a minimum lateral distance between a first end surface of a p-doped region of the pn or pin junction and a second end surface of an n-doped region of the pn or pin junction may be in a range from 0.5 to 3 times a diffusion length of at least one of the p-doped region or the n-doped region. This may allow for adapting lateral/vertical dimensions of the current sensing element to the current sensing function of the current sensing element and for reducing chip area consumption by the current sensing element.

Details with respect to structure, or function, or technical benefit of features described above with respect to a power semiconductor device likewise apply to the exemplary methods and measurement systems described herein. Processing the semiconductor body may comprise one or more optional additional features corresponding to one or more aspects mentioned in connection with the proposed concept or one or more examples described above or below.

An example of a measurement system may include a power semiconductor device comprising a bipolar power semiconductor element and a current sensing element. For example, the power semiconductor device may be configured according to any of the examples described herein. The measurement system may further include a measurement device configured to determine a measure for an on-current of the bipolar power semiconductor element by forcing a voltage between the first pin and the second pin of the current sensing element and measuring a current, e.g. a photo current, through the first pin and the second pin. The measure for the on-current of the bipolar power semiconductor element may be any parameter determined by measurement that allows for identifying the on-current.

For example, the measurement device may be further configured to determine a measure for the temperature of the bipolar power semiconductor element by forcing a current through the first pin and the second pin of the current sensing element and measuring a voltage between the first pin and the second pin, or by forcing a voltage between the first pin and the second pin of the current sensing element and measuring a current through the first pin and the second pin. The measure for the temperature of the bipolar power semiconductor element may be any parameter determined by measurement that allows for identifying the temperature of the bipolar power semiconductor element. In case the current sensing element is also configured to sense or to be used to sense the temperature, it may also be referred to as temperature/current sensing element. Preferably, the same pn or pin junction of the current sensing element may be used for both measuring the measure for the temperature and the measure for the on-current.

An example of the present disclosure relates to a method for determining a current of a power semiconductor device comprising a bipolar power semiconductor element and a current sensing element sensing element. The method may include determining a measure for an on-current of the bipolar power semiconductor element by forcing a voltage between a first pin and a second pin of the current sensing element sensing element and measuring a current, e.g. a photo current, through the first pin and the second pin. In case the current sensing element is also configured to sense or to be used to sense the temperature, it may also be referred to as temperature/current sensing element. Preferably, the same pn or pin junction of the current sensing element may be used for both measuring the measure for the temperature and the measure for the on-current.

For example, the method may further include determining a measure for a temperature of the bipolar power semiconductor element by forcing a current through the first pin and the second pin of the current sensing element and measuring a voltage between the first pin and the second pin, or by forcing a voltage between the first pin and the second pin of the current sensing element and measuring a current through the first pin and the second pin.

For example, the on-current of the bipolar power semiconductor element may be determined based on the measured current of the current sensing element and a calibration data set. For example, the calibration data set may be provided as part of or accompanying a data sheet of the power semiconductor device.

More details and aspects are mentioned in connection with the examples described above or below. The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

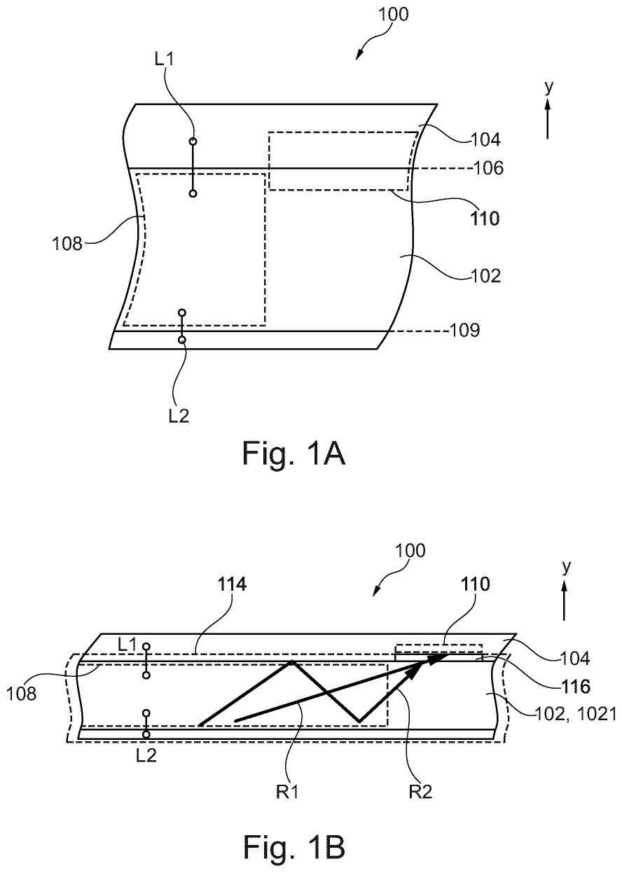

FIG. 1A is schematic partial cross-sectional view for illustrating an exemplary power semiconductor device 100. The power semiconductor device 100 includes a semiconductor body 102 and a wiring area 104 over a first surface 106, e.g. a top surface, of the semiconductor body 102.

The power semiconductor device 100 includes a bipolar power semiconductor element 108 comprising a first load electrode L1 in the wiring area 104, an active area in the semiconductor body 102, and a second load electrode L2 at a second surface 109 of the semiconductor body 102. The second surface 109 and the first surface 106 are opposed to one another along a vertical direction y.

The power semiconductor device 100 further includes a temperature/current sensing element 110. In some examples, the temperature/current sensing element 110 is at least partly formed in the semiconductor body 102. The temperature/current sensing element 110 may as well be at least partly formed in the wiring area 104 over the first surface 106. In some examples, a pn or pin junction of the temperature/current sensing element 110 is formed in the semiconductor body 102. In some other examples, the pn or pin junction of the temperature/current sensing element 110 is formed in the wiring area 104 over the first surface 106 of the semiconductor body 102. In some examples, the temperature/current sensing element 110 includes a plurality of pn or pin junctions electrically connected in series and/or in parallel. The plurality of pn or pin junctions may be formed in the semiconductor body 102, or in the wiring area 104, or in both the wiring area 104 and the semiconductor body 102.

FIG. 1B is schematic partial cross-sectional view for illustrating electromagnetic radiation caused by an on-current of the bipolar power semiconductor element 108 and passing to the temperature/current sensing element 110 for on-current sensing.

A path R1 is one example for a direct path from the bipolar power semiconductor element 108 through an optical window 114 to the temperature/current sensing element 104. A path R2 is one example for an indirect path from the bipolar power semiconductor element 108 through the optical window 114 to the temperature/current sensing element 110. The indirect path R2 is based on reflections of the electromagnetic radiation by reflective elements, e.g. metal layer(s), over the first surface 104 and over the second surface 109. The optical window 114 includes semiconductor material 1021, e.g. semiconductor material of the semiconductor body 102, and dielectric material 116, e.g. an interlayer dielectric such as a local oxidation of silicon (LOCOS) or a shallow trench isolation (STI) or a planar dielectric arranged between the temperature/current sensing element 110 and the semiconductor body 102. The dielectric material 116 may comprise silicon oxide. The dielectric material 116, e.g. the silicon oxide, of the optical window 114 may exhibit a transitivity of at least 10% or at least 20%.

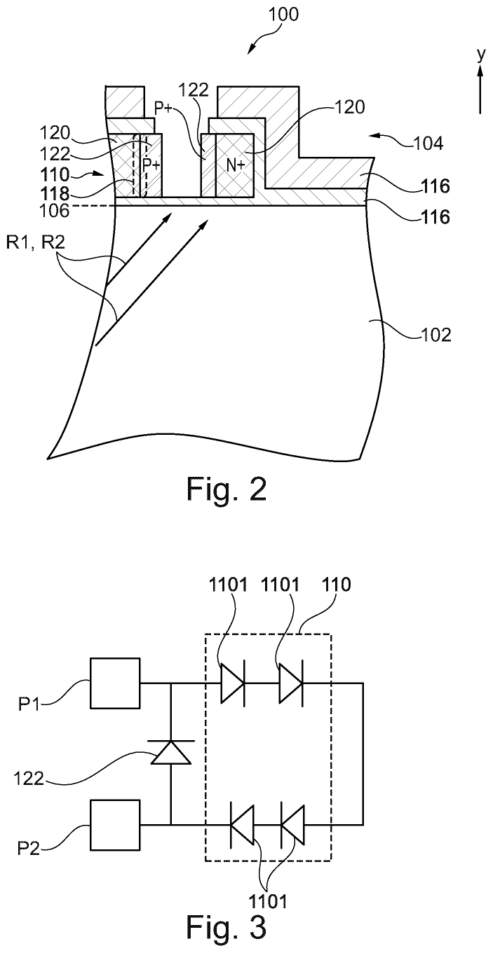

The schematic partial cross-sectional view of FIG. 2 illustrates one example of the bipolar power semiconductor element 108 arranged in the wiring area 104 over the first surface 106 of the semiconductor body 102. The bipolar power semiconductor element 108 includes a pn junction 118 between an n⁺-doped region 120 and a p⁺-doped region 122. An equipotential plane in the pn junction 118 is predominantly parallel to a vertical direction y.

The schematic circuit diagram of FIG. 3 illustrates one example of a temperature/current sensing element 110 that is formed by connecting four pn junction diodes 1101 in series between sensing pins P1, P2. A protection diode 124 is connected in parallel with the pn junction diodes 1101. Number and interconnection type (in series or in parallel) of the pn junction diodes 1101 may be varied and adapted to specific requirements.

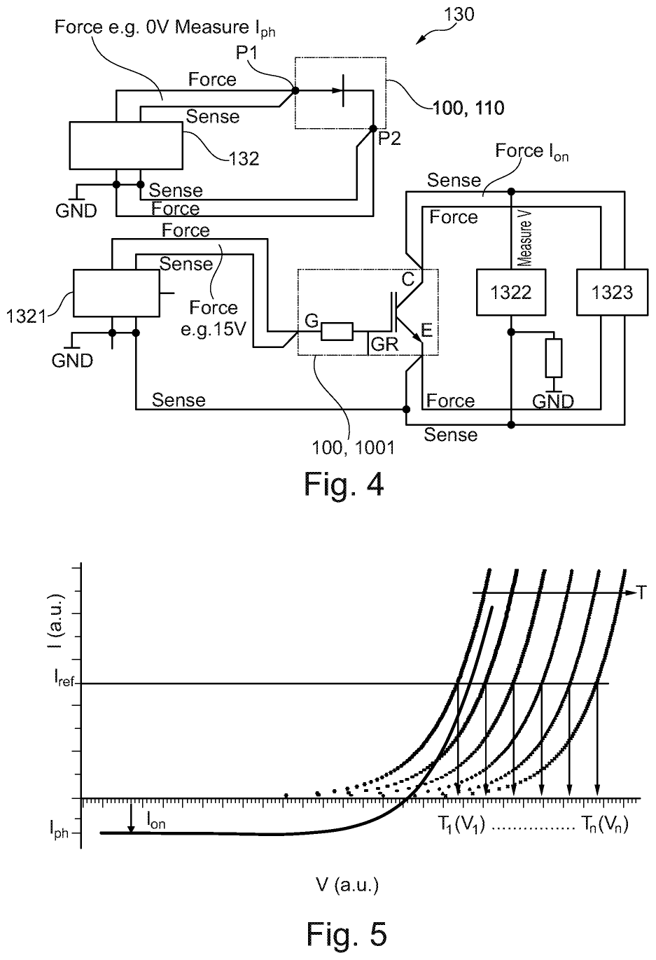

The schematic diagram of FIG. 4 exemplarily illustrates a measurement system 130. The measurement system 130 includes a power semiconductor device 100. The power semiconductor device 100 includes a power IGBT 1001 as an example of a bipolar power semiconductor element 108 and further includes a temperature/current sensing element 110. The measurement system 130 further includes a measurement device 132 configured to determine a measure for an on-current Ion of the power IGBT 1001 by forcing a voltage, e.g. 0 V, between a first pin P1 and a second pin P2 of the temperature/current sensing element 110 and sensing a current I through the first pin P1 and the second pin P2. The measurement device 132 or another measurement device includes sub-units 1321 (e.g. gate driver), 1322 (e.g. voltage meter), 1323 (e.g. current source) for testing the IGBT 1001. The sub-units 1311,1322, 1323 may be used for calibrating the temperature/current sensing element 110. For example, by applying a gate voltage, e.g. 15 V, to a gate G of the IGBT 1001 and forcing an on-current Ion through emitter E and collector C of the IGBT 1001, electromagnetic radiation caused by the on-current Ion is passed to the bipolar power semiconductor element 108 and measured as a photo current Iph related to the specific on-current Ion. By varying Ion, calibration data correlating sensed photo current Iph and on-state current Ion of the IGBT 1001 can be achieved.

The measurement device 132 may be configured to determine the measure for temperature T in the semiconductor body 102, Ion of the power IGBT 1001 by forcing a current, preferably of opposite direction than the photo current Iph, e.g. at least 1 μA, through the first pin P1 and the second pin P2 of the temperature/current sensing element 110 and sensing the resulting voltage V between the first pin P1 and the second pin P2. The photo current Iph may for example range from 1 μA to 1 mA.

The schematic graph of FIG. 5 illustrates a current I versus voltage V curve of a sensing pn or pin junction of a temperature/current sensing element 110. For a fixed bias current Iref, sensed voltages V1 . . . Vn are associated with temperatures T1 . . . Tn of the temperature/current sensing element 110. An increase in temperature T in the semiconductor body 102 of the temperature/current sensing element 110 (representative for e.g. the IGBT 1001 in FIG. 4) leads to an increase of the sensed voltage for a fixed bias current Iref. As described with reference to FIG. 4, the on-current Ion in the bipolar power semiconductor element, e.g. the IGBT 1001 in FIG. 4, causes emission of electromagnetic radiation that is sensed as a photo current Iph by the temperature/current sensing element 110. An increase in the on-current Ion leads to an increase of the sensed photo current Iph for a reference voltage, e.g. 0V.

In general, at least two arbitrary pairs of values of the current I versus voltage V curve may be measured to determine both the measure for the on-current Ion and the measure for temperature. By those two pairs of values the current I versus voltage V curve may be represented sufficiently to derive both the measure for the on-current Ion and the measure for temperature. Mathematically, the current I versus voltage V curve may be well-defined by said two arbitrary pairs of values. Each pair of said two pairs of values may be determined by either forcing a voltage between the first pin P1 and the second pin P2 of the temperature/current sensing element 110 and sensing a current I through the first pin P1 and the second pin P2 or forcing a current through the first pin P1 and the second pin P2 of the temperature/current sensing element 110 and sensing a voltage I between the first pin P1 and the second pin P2. Of course, more than two arbitrary pairs of values may be determined to provide better reliability and/or accuracy.

For example, the temperature T in the semiconductor body 102 or the on-current Ion may be calculated or determined by the measurement device 132. The measurement device 132 may include a microprocessor, digital signal processor, IC, FPGA, or the like, configured to calculate or determine the temperature T and/or the on-current and/or the respective measure for the temperature T and/or the on-current.

The aspects and features mentioned and described together with one or more of the previously detailed examples and figures, may as well be combined with one or more of the other examples in order to replace a like feature of the other example or in order to additionally introduce the feature to the other example.

What is claimed is:

1. A power semiconductor device, comprising:
a semiconductor body;
a wiring area over a first surface of the semiconductor body;
a bipolar power semiconductor element comprising a first load electrode in the wiring area, an active area in the semiconductor body, and a second load electrode at a second surface of the semiconductor body;
a current sensing element including a pn or pin junction; and
an optical window configured to allow electromagnetic radiation caused by an on-current of the bipolar power semiconductor element to pass to the current sensing element.

2. The power semiconductor device of claim 1, wherein the optical window comprises semiconductor material and dielectric material.

3. The power semiconductor device of claim 1, wherein the current sensing element is arranged in the wiring area.

4. The power semiconductor device of claim 1, wherein the pn or pin junction is a monocrystalline or a polycrystalline or a nanocrystalline silicon pn or pin junction.

5. The power semiconductor device of claim 1, wherein a surface of the current sensing element is textured.

6. The power semiconductor device of claim 1, further comprising a reflection layer configured to reflect the electromagnetic radiation back into the optical window.

7. The power semiconductor device of claim 1, further comprising deep level impurities in the current sensing element.

8. The power semiconductor device of claim 7, wherein the semiconductor body is a silicon semiconductor body and the deep level impurities include at least one of selenium, sulfur, thallium, and zinc.

9. The power semiconductor device of claim 1, wherein the current sensing element includes a plurality of the pn or pin junctions connected in series or in parallel.

10. The power semiconductor device of claim 1, further comprising a surface recombination reduction structure on a surface of the current sensing element.

11. The power semiconductor device of claim 1, wherein an equipotential plane in the pn or pin junction is predominantly parallel to a vertical direction.

12. The power semiconductor device of claim 1, wherein a minimum lateral distance between a first end surface of a p-doped region of the pn or pin junction and a second end surface of an n-doped region of the pn or pin junction is in a range from 0.5 to 3 times a diffusion length of at least one of the p-doped region or the n-doped region.

13. The power semiconductor device of claim 1, wherein the current sensing element is thermally coupled to the semiconductor body.

14. A measurement system, comprising:
a power semiconductor device comprising a bipolar power semiconductor element and a current sensing element; and
a measurement device configured to determine a measure for an on-current of the bipolar power semiconductor element by forcing a voltage between a first pin and a second pin of the current sensing element and measuring a current through the first pin and the second pin.

15. The measurement system of claim 14, wherein the measurement device is further configured to determine a measure for a temperature of the bipolar power semiconductor element by forcing a current through the first pin and the second pin of the current sensing element and measuring a voltage between the first pin and the second pin, or by forcing a voltage between the first pin and the second pin of the current sensing element and measuring a current through the first pin and the second pin.

16. The measurement system of claim 14, wherein the current sensing element is thermally coupled to the semiconductor body.

17. The measurement system of claim 14, wherein the current sensing element is arranged in the wiring area.

18. A method for determining a current of a power semiconductor device comprising a bipolar power semiconductor element and a current sensing element, the method comprising:
determining a measure for an on-current of the bipolar power semiconductor element by forcing a voltage between a first pin and a second pin of the current sensing element and measuring a current through the first pin and the second pin.

19. The method of claim 18, further comprising determining a measure for a temperature of the bipolar power semiconductor element by forcing a current between the first pin and the second pin of the current sensing element and measuring a voltage between the first pin and the second pin, or by forcing a voltage between the first pin and the second pin of the current sensing element and measuring a current through the first pin and the second pin.

20. The method of claim 18, wherein the on-current of the bipolar power semiconductor element is determined based on the measured current of the current sensing element and a calibration data set.

21. The method of claim 18, wherein the current sensing element is thermally coupled to the semiconductor body.

22. The method of claim 18, wherein the current sensing element is arranged in the wiring area.
